(19) United States
(12) Patent Application Publication
(10) Pub. No.: US 2010/0206372 A1
(43) Pub. Date: Aug. 19, 2010

(54) Photovoltaic Devices Including Heterojunctions

(75) Inventors: Benyamin Buller, Sylvania, OH (US); Rui Shao, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/620,984

(22) Filed: Nov. 18, 2009

Related U.S. Application Data
(60) Provisional application No. 61/116,012, filed on Nov. 19, 2008.

(51) Int. Cl. H01L 31/0296; H01L 31/0352; H01L 31/0256

(52) U.S. Cl. 136/256; 438/94; 257/E31.015; 257/E31.126

(57) ABSTRACT

A photovoltaic cell can include a substrate having a transparent conductive oxide layer, a heterojunction layer, and a cadmium telluride layer. The layers can be deposited by sputtering or by chemical vapor deposition.

### CLAIM OF PRIORITY

This application claims priority to U.S. Provisional Patent Application No. 61/116,012, filed on Nov. 19, 2008, which is incorporated by reference in its entirety.

### TECHNICAL FIELD

This invention relates to photovoltaic devices and heterojunctions.

### BACKGROUND

During the fabrication of photovoltaic devices, layers of semiconductor material can be applied to a substrate with one layer serving as a window layer and a second layer serving as the absorber layer. The window layer can allow the penetration of solar radiation to the absorber layer, where the optical power is converted into electrical power. Some photovoltaic devices can use transparent thin films that are also conductors of electrical charge.

The conductive thin films can include transparent conductive layers that contain a transparent conductive oxide (TCO), such as cadmium stannate. The TCO can allow light to pass through a semiconductor window layer to the active light absorbing material and also serve as an ohmic contact to transport photo-generated charge carriers away from the light absorbing material. A back electrode can be formed on the back surface of a semiconductor layer. The back electrode can include electrically conductive material.

### SUMMARY

In general, a photovoltaic device can include a transparent conductive layer on a substrate, a first semiconductor layer including a M₁₋ₓGₓO_{y} compound semiconductor, the first semiconductor layer positioned over the transparent conductive layer, and a second semiconductor layer including a cadmium telluride compound semiconductor, the second semiconductor layer positioned between a first semiconductor layer and a back metal contact. In the M₁₋ₓGₓO_{y} compound semiconductor, the M may be one of zinc or tin and the G may be one of aluminum, silicon, or zirconium and y, the oxygen content, may be determined by x and the valences of element M and G as in a stoichiometric compound, where y is equal to ((valence of M)(1−x)+(valence of G)(x))/2). Vacancies can be permitted. The M₁₋ₓGₓO_{y} compound and the cadmium telluride compound can form a heterojunction. The cadmium telluride compound can be an alloy or doped composition of cadmium telluride.

A method of manufacturing a photovoltaic device can include depositing a first semiconductor layer on a substrate, the first semiconductor layer including a M₁₋ₓGₓO_{y} compound semiconductor and depositing a second semiconductor layer between the first semiconductor layer and a back metal contact, the second semiconductor layer including a cadmium telluride compound. The method can further include depositing an interfacial layer between the first semiconductor layer and the second semiconductor layer to enhance a rectifying junction between the M₁₋ₓGₓO_{y} semiconductor and cadmium telluride compound.

A system for generating electrical energy can include a multilayered photovoltaic cell including a transparent conductive layer on a substrate, a first semiconductor layer including a M₁₋ₓGₓO_{y} compound semiconductor, the first semiconductor layer positioned over the transparent conductive layer, a second semiconductor layer including a cadmium telluride compound semiconductor, the second semiconductor layer positioned between a first semiconductor layer and a back metal contact, and a first electrical connection connected to a transparent conductive layer, and a second electrical connection connected to a back metal electrode adjacent to a second semiconductor layer. A system can further include an interfacial layer that enhances the rectifying junction between the M₁₋ₓGₓO_{y} and cadmium telluride compound semiconductors.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic of a photovoltaic device having multiple layers.

FIG. 2 is a schematic of a system for generating electrical energy.

### DETAILED DESCRIPTION

Photovoltaic devices can include a rectifying junction between p-type or high resistivity cadmium telluride and a doped or undoped n-type semiconductor. The n-type semiconductor can be covered with a high resistivity buffer layer that may contain doped or undoped transparent oxides such as SnO₂, SiO₂, SnO₂:Cd, SnO₂:Zn or CdZnO₂. Previous attempts at constructing junctions between CdTe and various II-VI n-type semiconductors have not achieved commercially viable performance Likewise, previous attempts at constructing junctions between CdTe to p-type materials including such as Cu₂Te and ZnTe have not achieved commercially viable performance.

Both rectifying and low resistance junctions with a semiconductor layer, such as a semiconductor layer including a cadmium telluride, may include thin film interfacial layers designed to improve electrical performance of the devices. Interfacial layers can include, for example, oxides between the cadmium telluride and metal electrode of the photovoltaic device. Interfacial layers can be deposited by wet chemistry, sputter etching and sputter deposition, e-beam evaporation followed by thermal annealing, chemical bath deposition, atomic layer deposition method and other methods known to those in the art.

A preferred process would be to make the cadmium stannate and then deposit on top of it a buffer layer that is in ideal band alignment to the cadmium telluride. Because oxides are easily made in a reactive sputtering process during the making of the cadmium stannate, there is a huge advantage for finding oxides that can meet the requirements.

In addition to this, since cadmium stannate is going through phase transformation after deposition it would be advantageous to have a buffer layer which is more inert and stable than SnO₂.

Both SnO₂ and ZnO have a conduction band offset to CdTe of about −0.5V. A possible route would be to replace ZnO or SnO₂ by a material which is a compound of ZnO or SnO₂ with a higher band offset oxide. Such higher conduction band offset materials are: SiO₂, Al₂O₃ and ZrO₂. All of them have a positive conduction band offset ranging from 0.85V for ZrO₂, 2V for Al₂O₃, and more than 3V for SiO₂.

The device structure can be: substrate/barrier-color suppression stack/cadmium stannate/M₁₋ₓGₓO_{y}/CdTe/back contact stack, where M is Zn or Sn, and G is Al, Si or Zr. In M₁₋ₓGₓO_{y}, the oxygen content, y, may be determined by x and the valences of element M and G as in a stoichiometric compound. The layer does not need to be strongly conductive. Instead, the layer can be selected to match or closely match the conduction band offset of cadmium telluride.

For M₁₋ₓGₓO_{y}, preferred values of x are as follows: for Sn₁₋ₓSiₓO_{y}, x can be in the range of 0.05 to 0.25. For Sn₁₋ₓAlₓO_{y}, x can be in the range of 0.10 to 0.30. For Sn₁₋ₓZrₓO_{y}, x can be in the range of 0.30 to 0.60. For Zn₁₋ₓSiₓO_{y}, x can be in the range of 0.10 to 0.25. For Zn₁₋ₓAlₓO_{y}, x can be in the range of 0.05 to 0.30. For Zn₁₋ₓZrₓO_{y}, x can be in the range of 0.30 to 0.50. Thickness of the layer of M₁₋ₓGₓO_{y} can be in the range of 300 Angstroms to 1500 Angstroms

The substrate/barrier-color suppression stack/cadmium stannate/M₁₋ₓGₓO_{y} can be made using room temperature sputtering, e.g., physical vapor deposition, from ceramic or metallic targets (in a reactive sputtering process). M₁₋ₓGₓO_{y} may be deposited in the same vacuum sputter coater where the cadmium stannate is deposited. The deposition process may involve reactive sputtering of an alloy target M₁₋ₓGₓ using an atmosphere of argon and oxygen mixture in the vacuum sputtering coater. After the deposition of this stack, the substrate, which may be glass, can be optionally annealed. After annealing the device can be coated with cadmium telluride, for example, by vapor transport deposition.

One advantage of using this particular stack is that M₁₋ₓGₓO_{y} can be made quickly and efficiently in a reactive sputtering process from extremely cheap targets. M₁₋ₓGₓO_{y} has the potential to be a better diffusion barrier and more stable and inert structure than SnO₂ or ZnO, facilitating phase transformation of cadmium stannate that is isolated from the annealing environment. M₁₋ₓGₓO_{y} may not be damaged by the cadmium stannate phase transformation and may maintain proper band alignment to CdTe due to its improved inertness compared to SnO₂ or Zn. M₁₋ₓGₓO_{y} is a single layer that will serve both as a buffer layer as well as a heterojunction partner to CdTe, eliminating a process step (CdS) and eliminating a significant problem (CdS coverage or pinholes). M₁₋ₓGₓO_{y} can be made significantly thicker than CdS due to its high band gap, and thus its reduced absorption.

In contrast to previous devices and methods, the claimed devices and methods incorporate innovative combinations of semiconductors and employs device architectures that overcome limitations on existing device structures and enable enhanced photovoltaic device performance.

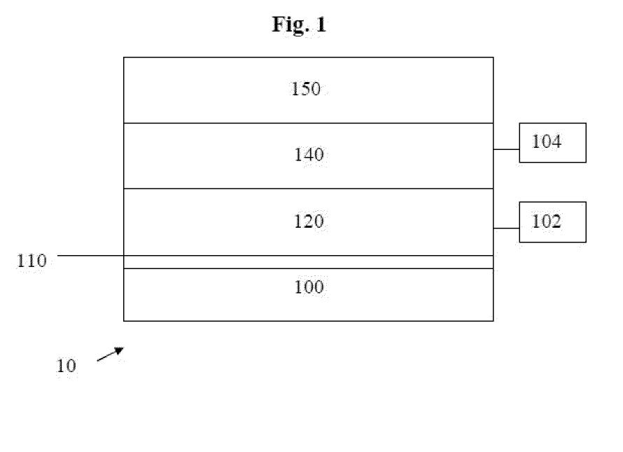

Referring to FIG. 1, a photovoltaic device 10 can include a transparent conductive layer 110 on a substrate 100, a first semiconductor layer 120, the first semiconductor layer including a zinc-metal oxide or silicon metal oxide semiconductor 102, the first semiconductor layer positioned over the transparent conductive layer, and a second semiconductor layer 140, the second semiconductor layer including a cadmium telluride semiconductor 104, the second semiconductor layer positioned between a first semiconductor layer and a back metal contact 150.

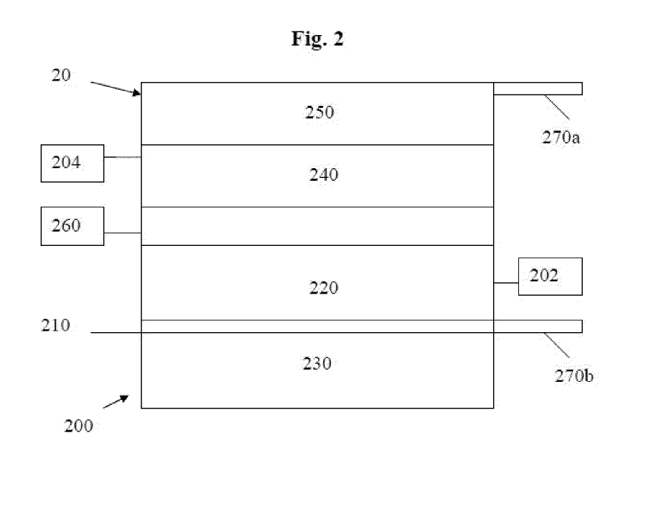

Referring to FIG. 2, a system 200 for generating electrical energy can include a multilayered photovoltaic cell 20 including a transparent conductive layer 210 on a substrate 230, a first semiconductor layer 220, the first semiconductor layer including a zinc-metal oxide or silicon metal oxide semiconductor 202, the first semiconductor layer positioned over the transparent conductive layer, a second semiconductor layer 240, the second semiconductor layer including a cadmium telluride semiconductor 204, the second semiconductor layer positioned between a first semiconductor layer and a back metal contact 250, and a first electrical connection 270b connected to a transparent conductive layer, and a second electrical connection 270a connected to a back metal electrode adjacent to a second semiconductor layer. A system can further include an interfacial layer 260 that enhances a rectifying junction between the cadmium telluride layer 240 and the M₁₋ₓGₓO_{y} semiconductor layer 220.

A first semiconductor layer can include a wide bandgap semiconductor. A first semiconductor layer can include a zinc-metal oxide or silicon metal oxide semiconductor or alloys thereof. A zinc-metal oxide or silicon metal oxide semiconductor compound can be a material with a chemical formula M₁₋ₓGₓO_{y}, wherein M is selected from a group including zinc and tin and G is selected from a group including aluminum, silicon, and zirconium. A zinc-metal oxide or silicon metal oxide can be a zinc aluminum oxide, for example.

A second semiconductor layer can include a cadmium telluride compound or alloys thereof. A heterojunction can be formed between the M₁₋ₓGₓO_{y} compound and the CdTe compound. An interfacial layer can enhance a rectifying junction, such as a rectifying heterojunction between a M₁₋ₓGₓO_{y} compound and a CdTe compound.

An interfacial layer can be positioned on either side of a semiconductor layer or on both sides of a semiconductor layer. A semiconductor layer can include cadmium telluride for example. Low resistance hole transport between a semiconductor layer and a metal contact or a semiconductor layer and another semiconductor layer can be achieved by using high work function materials.

A method of manufacturing a photovoltaic device can include depositing a first semiconductor layer on a substrate, the first semiconductor layer including a M₁₋ₓGₓO_{y} compound semiconductor and depositing a second semiconductor layer between the first semiconductor layer and a back metal contact, the second semiconductor layer including a cadmium telluride compound. The method can further include depositing an interfacial layer between the first semiconductor layer and the second semiconductor layer to enhance a rectifying junction between the M₁₋ₓGₓO_{y} semiconductor and cadmium telluride compound.

A system for generating electrical energy can include a multilayered photovoltaic cell including a transparent conductive layer on a substrate, a first semiconductor layer including a M₁₋ₓGₓO_{y} compound semiconductor, the first semiconductor layer positioned over the transparent conductive layer, a second semiconductor layer including a CdTe compound semiconductor, the second semiconductor layer positioned between a first semiconductor layer and a back metal contact, and a first electrical connection connected to a transparent conductive layer and a second electrical connection connected to a back metal electrode adjacent to a second semiconductor layer. A system can further include an interfacial layer that enhances a rectifying junction between the M₁₋ₓGₓO_{y} semiconductor and cadmium telluride compound.

Previous attempts to treat the surfaces of a semiconductor layers typically required heavy doping with copper. For example a semiconductor could be positioned adjacent to a copper-doped film. Alternatively, an undoped zinc telluride film could be positioned adjacent to a cadmium telluride layer and a second degenerately copper-doped zinc telluride film could be positioned the opposite side of the undoped zinc telluride film. With previous methods, it was unclear what role was played by the matching the VBM of the cadmium telluride and zinc telluride films and what role was played by the copper dopant. Previous methods have not included the use of high work function p-type TCOs to treat semiconductor layers, in part due to the difficulty in producing p-type TCOs with sufficiently high electrical conduction and optical transparency to play the role of n-type TCOs in other semiconductor devices. Semiconductors with a bandgap greater than cadmium telluride and which match the VBM of cadmium telluride also serve to reflect electrons within the cadmium telluride from the cadmium telluride-wide bandgap interface.

The interfaces between a first semiconductor layer and a second semiconductor layer, or between a semiconductor layer and a metal layer, can have significant impact on device performance. For example, interfaces may provide electrical defects that produce mid-gap energy levels to promote the recombination of electrons from the conduction band with holes from the valence band. Recombination of electrons and holes can be a loss mechanism for photovoltaic devices. Negative impacts of interfaces on device performance can be mitigated by several ways, such as careful selection of heterojunction partners to minimize the lattice mismatch between the two materials, grading material composition from one heterojunction material to the other, and passivating the interface with oxygen, sulfur, hydrogen or other materials to tie up dangling bonds responsible for the mid-gap energy states.

Amphiphilic molecules can also be used at the interfaces to alter electrical performance by creating a dipole layer on surfaces or at interfaces. Furthermore, even in the absence of lattice mismatch, the symmetry of a crystal lattice can be distorted by the existence of an interface between two materials of different electrical properties such that dipole layers form at the interface due to differences in the nature of chemical bonding between atoms of the heterojunction partners.

Both rectifying and low resistance junctions with a semiconductor layer, such as a semiconductor layer including a cadmium telluride, may include thin film interfacial layers designed to improve electrical performance of the devices. Interfacial layers can include, for example, oxides between the cadmium telluride and metal electrode of the photovoltaic device. Interfacial layer can be by wet chemistry, sputter etching and sputter deposition, e-beam evaporation followed by thermal annealing, chemical bath deposition, or atomic layer deposition method.

Previous devices employ a conventional cadmium sulfide layer as a wide bandgap n-type heterojunction partner to cadmium telluride layer. However, a thick cadmium sulfide layer absorbs photons equivalent to approximately 6 mA/cm² out of approximately 30 mA/cm² that could be absorbed by the cadmium telluride. Thus, it can be advantageous to use a thin cadmium sulfide layer to pass light with energy above the cadmium sulfide bandgap. The lower limit on cadmium sulfide layer thickness can be due to the requirement that the heterojunction partner contain sufficient charge to balance the negative space charge in the cadmium telluride. An n-type junction to cadmium telluride can therefore contain a second high resistivity n-type buffer layer on the side of the cadmium sulfide layer opposite to the cadmium telluride layer. The high resistivity buffer layer can both add to the positive space charge and mitigate effects of shunts through the cadmium sulfide film. Such buffer layers, are described, for example in U.S. Pat. No. 5,279,678, which is incorporated by reference in its entirety.

An improved photovoltaic device can include an interfacial layer that accounts for the chemical potential of a semiconductor at the interface between a semiconductor layer, such as a cadmium telluride layer, and a high work function or wide bandgap semiconductor. Low resistance transport of holes between the semiconductor layer, such as a cadmium telluride layer and a back metal electrode can be achieved using a high work function or wide bandgap semiconductor in an interfacial layer between the semiconductor layer and the back metal electrode.

A photovoltaic cell can have multiple layers. The multiple layers can include a bottom layer that can be a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic cell.

The bottom layer can be a transparent conductive layer, and can be, for example, a transparent conductive oxide such as cadmium stannate oxide, tin oxide, or tin oxide doped with fluorine. Deposition of a semiconductor layer at high temperature directly on the transparent conductive oxide layer can result in reactions that negatively impact of the performance and stability of the photovoltaic device. Deposition of a capping layer of material with a high chemical stability (such as silicon dioxide, dialuminum trioxide, titanium dioxide, diboron trioxide and other similar entities) can significantly reduce the impact of these reactions on device performance and stability. The thickness of the capping layer should be minimized because of the high resistivity of the material used. Otherwise a resistive block counter to the desired current flow may occur. A capping layer can reduce the surface roughness of the transparent conductive oxide layer by filling in irregularities in the surface, which can aid in deposition of the window layer and can allow the window layer to have a thinner cross-section. The reduced surface roughness can help improve the uniformity of the window layer. Other advantages of including the capping layer in photovoltaic cells can include improving optical clarity, improving consistency in band gap, providing better field strength at the junction and providing better device efficiency as measured by open circuit voltage loss. Capping layers are described, for example, in U.S. Patent Publication 20050257824, which is incorporated by reference in its entirety.

The window layer and the absorbing layer can include, for example, a binary semiconductor such as a layer of M₁₋ₓGₓO_{y} coated by a layer of cadmium telluride. A top layer can cover the semiconductor layers. The top layer can include a metal such as, for example, aluminum, molybdenum, nickel, titanium, tungsten, or alloys thereof.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports substrate into a series of one or more deposition stations for depositing layers of material on the exposed surface of the substrate. Conveyors are described in provisional U.S. application Ser. No. 11/692,667, which is incorporated by reference in its entirety.

The deposition chamber can be heated to reach a processing temperature of not less than about 450° C. and not more than about 700° C., for example the temperature can range from 450-550° C., 550-650° C., 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations with its own vapor distributor and supply. The distributor can be in the form of a spray nozzle with varying nozzle geometries to facilitate uniform distribution of the vapor supply.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The transparent conductive layer can be a transparent conductive oxide, such as a metallic oxide like cadmium stannate oxide. This layer can be deposited between the front contact and the first semiconductor layer, and can have a resistivity sufficiently high to reduce the effects of pinholes in the first semiconductor layer. Pinholes in the first semiconductor layer can result in shunt formation between the second semiconductor layer and the first contact resulting in a drain on the local field surrounding the pinhole. A small increase in the resistance of this pathway can dramatically reduce the area affected by the shunt.

A capping layer can be provided to supply this increase in resistance. The capping layer can be a very thin layer of a material with high chemical stability. The capping layer can have higher transparency than a comparable thickness of semiconductor material having the same thickness. Examples of materials that are suitable for use as a capping layer include silicon dioxide, dialuminum trioxide, titanium dioxide, diboron trioxide and other similar entities. Capping layer can also serve to isolate the transparent conductive layer electrically and chemically from the first semiconductor layer preventing reactions that occur at high temperature that can negatively impact performance and stability. The capping layer can also provide a conductive surface that can be more suitable for accepting deposition of the first semiconductor layer. For example, the capping layer can provide a surface with decreased surface roughness.

A number of embodiments have been described. Nevertheless, it will be understood that various modifications may be made without departing from the spirit and scope of the invention. For example, the semiconductor layers can include a variety of other materials, as can the materials used for the buffer layer and the capping layer. In addition, the device may contain interfacial layers between a second semiconductor layer and a back metal electrode to reduce resistive losses and recombination losses at the interface between the second semiconductor and the back metal electrode. Accordingly, other embodiments are within the scope of the following claims.

What is claimed is:

1. A photovoltaic device comprising:
a transparent conductive layer on a substrate;
a first semiconductor layer, the first semiconductor layer positioned over the transparent conductive layer; and
a second semiconductor layer, the second semiconductor layer positioned between the first semiconductor layer and a back metal contact,
wherein the first semiconductor layer is an M₁₋ₓGₓO_{y} semiconductor, the M is selected from the group consisting of zinc and tin, and the G is selected from the group consisting of aluminum, silicon, and zirconium.

2. The device of claim 1, wherein the first semiconductor layer includes a zinc aluminum oxide.

3. The device of claim 2, wherein, in the Zn₁₋ₓAlₓO_{y}, x is in the range of 0.05 to 0.30.

4. The device of claim 1, wherein the first semiconductor layer includes a zinc silicon oxide.

5. The device of claim 4, wherein, in the Zn₁₋ₓSiₓO_{y}, x is in the range of 0.10 to 0.25.

6. The device of claim 1, wherein the first semiconductor layer includes a zinc zirconium oxide.

7. The device of claim 6, wherein, in the Zn₁₋ₓZrₓO_{y}, x is in the range of 0.30 to 0.50.

8. The device of claim 1, wherein the first semiconductor layer includes a tin aluminum oxide.

9. The device of claim 8, wherein, in the Sn₁₋ₓAlₓO_{y}, x is in the range of 0.10 to 0.30.

10. The device of claim 1, wherein the first semiconductor layer includes a tin silicon oxide.

11. The device of claim 10, wherein, in the Sn₁₋ₓSiₓO_{y}, x is in the range of 0.05 to 0.25.

12. The device of claim 1, wherein the first semiconductor layer includes a tin zirconium oxide.

13. The device of claim 12, wherein, in the Sn₁₋ₓZrₓO_{y}, x is in the range of 0.30 to 0.60.

14. The device of claim 1, wherein the thickness of the M₁₋ₓGₓO_{y} is between 300 Angstroms to 1500 Angstroms.

15. The device of claim 1, wherein the transparent conductive layer is a transparent conductive oxide.

16. The device of claim 1, wherein the transparent conductive layer is a cadmium stannate.

17. The device of claim 1, wherein the second semiconductor layer is a cadmium telluride.

18. The device of claim 1, wherein the second semiconductor layer is an alloy of cadmium telluride.

19. The device of claim 1, wherein the second semiconductor layer is a doped composition of cadmium telluride.

20. A method of manufacturing a photovoltaic device comprising:
depositing a first semiconductor layer on a substrate, the first semiconductor layer including a cadmium stannate semiconductor;
depositing a second semiconductor layer on the first semiconductor layer, the second semiconductor layer including an M₁₋ₓGₓO_{y} semiconductor, the M is selected from the group consisting of zinc and tin, and the G is selected from the group consisting of aluminum, silicon, and zirconium; and
depositing a third semiconductor layer between the second semiconductor layer and a back metal contact, the third semiconductor layer including a cadmium telluride semiconductor.

21. The method of claim 20, wherein the depositing a second semiconductor layer step involves reactive sputtering of an alloy target M₁₋ₓGₓ using an atmosphere of argon and oxygen mixture in the vacuum sputtering coater.

22. The method of claim 20, wherein the depositing a first semiconductor layer step and the depositing a second semiconductor layer step occurs in a single vacuum sputtering coater.

23. A system for generating electrical energy comprising:
a multilayered photovoltaic cell including
a transparent conductive layer on a substrate,
an first semiconductor layer including an M₁₋ₓGₓO_{y} semiconductor, the M is selected from the group consisting of zinc and tin, and the G is selected from the group consisting of aluminum, silicon, and zirconium, the first semiconductor layer positioned over the transparent conductive layer,
a second semiconductor layer including a cadmium telluride semiconductor, the second semiconductor layer positioned between the first semiconductor layer and a back metal contact,
a first electrical connection connected to the transparent conductive layer; and
a second electrical connection connected to the back metal electrode adjacent to the second semiconductor layer.

24. The system of claim 23, wherein the transparent conductive layer is a cadmium stannate.

25. The system of claim 23, wherein the second semiconductor layer is an alloy of cadmium telluride.

26. The system of claim 23, wherein the second semiconductor layer is a doped composition of cadmium telluride.

27. The system of claim 23, wherein the second semiconductor layer is a cadmium telluride.

28. The system of claim 23, wherein the first semiconductor layer includes zinc aluminum oxide.

29. The system of claim 28, wherein, in the Zn₁₋ₓAlₓO_{y}, x is in the range of 0.05 to 0.30.

30. The system of claim 23, wherein the first semiconductor layer includes zinc silicon oxide.

31. The system of claim 30, wherein, in the Zn₁₋ₓSiₓO_{y}, x is in the range of 0.10 to 0.25.

32. The system of claim 23, wherein the first semiconductor layer includes zinc zirconium oxide.

33. The system of claim 32, wherein, in the Zn₁₋ₓZrₓO_{y}, x is in the range of 0.30 to 0.50.

34. The system of claim 23, wherein the first semiconductor layer includes tin aluminum oxide.

35. The system of claim 8, wherein, in the Sn₁₋ₓAlₓO_{y}, x is in the range of 0.10 to 0.30.

36. The system of claim 23, wherein the first semiconductor layer includes tin silicon oxide.

37. The system of claim 36, wherein, in the Sn₁₋ₓSiₓO_{y}, x is in the range of 0.05 to 0.25.

38. The system of claim 23, wherein the first semiconductor layer includes tin zirconium oxide.

39. The system of claim 38, wherein, in the Sn₁₋ₓZrₓO_{y}, x is in the range of 0.30 to 0.60.

40. The system of claim 23, wherein the thickness of the M₁₋ₓGₓO_{y} is between 300 Angstroms to 1500 Angstroms.
